(19) United States
(12) Patent Application Publication
(10) Pub. No.: US 2026/0013209 A1
(43) Pub. Date: Jan. 8, 2026

(54) SHIELDED GATE TRENCH DEVICE AND A METHOD FOR FABRICATING THE SAME

(71) Applicant: Hangzhou Silicon-Magic Semiconductor Technology Co.,Ltd, Hangzhou (CN)

(72) Inventors: Shida Dong, Hangzhou (CN); Jian Liu, Torrance, CA (US)

(73) Assignee: Hangzhou Silicon-Magic Semiconductor Technology Co.,Ltd, Hangzhou (CN)

(21) Appl. No.: 19/243,021

(22) Filed: Jun. 19, 2025

(30) Foreign Application Priority Data
Jul. 3, 2024 (CN) 2024108926401

(51) Int. Cl. H10D 84/00; H10D 84/01

(52) U.S. Cl. CPC H10D 84/141; H10D 84/0109

(57) ABSTRACT

A semiconductor device having: a base layer including transistor regions and diode regions alternately arranged along a predetermined direction; first trenches formed in the transistor regions, wherein in each one of the first trenches, a control gate polysilicon layer is formed in an upper portion of the first trench, sidewalls and a bottom of the control gate polysilicon layer are wrapped by a control gate oxide layer; and second trenches formed in the diode regions, wherein in each one of the second trenches, a third gate polysilicon layer is formed in an upper portion of the second trench, sidewalls and a bottom of the third gate polysilicon layer are wrapped by a third gate oxide layer; wherein a thickness of the control gate oxide layer is greater than the third shielded gate oxide layer.

### CROSS-REFERENCE TO RELATED APPLICATION

This application claims the benefit of Chinese patent application No. 202410892640.1, filed on Jul. 3, 2024, which is incorporated herein by reference in its entirety.

### TECHNICAL FIELD

The present disclosure belongs to the technical field of semiconductors, and in particular to a shielded gate trench device and a method for fabricating the same.

### BACKGROUND

A shielded gate trench (SGT) structure is an advanced MOSFET technology that uses deep trench process to add a shielding electrode below a gate electrode, which is connected to a source electrode to achieve a function of shielding a gate and a drift region, thereby reducing the Miller capacitance and gate charge, accelerating a switching speed, and reducing a switching loss.

In a method for fabricating an SGT structure, a fabrication of a control gate involves the following process: etching of oxide layer→deposition of polysilicon→etching of polysilicon.

A source-drain voltage Vsd of the SGT structure fabricated by adopting the current process is relatively high and generally 0.7 V to 0.8 V, and a reverse recovery time is long, resulting in low circuit efficiency.

Therefore, how to provide an SGT structure and a method for fabricating the same to reduce the source-drain voltage Vsd, and reduce a reverse recovery charge Qrr and the reverse recovery time Trr, and improve a circuit efficiency, has become an important technical problem that needs to be solved urgently by those skilled in the art.

### SUMMARY

An objective of the present invention is to provide a shielded-gate trench device with an MGD (metal-gated diode) structure and a fabrication method thereof. This solution addresses the issues of high source-drain voltage (Vsd) and prolonged reverse recovery time in conventional shielded-gate trench devices, which result in low circuit efficiency.

An example of the present disclosure relates to a method for fabricating a shielded gate trench device. The method includes: providing a base layer having a substrate and an epitaxial layer overlying the substrate, wherein the base layer includes transistor regions and diode regions arranged alternately along a predetermined direction; forming first trenches and second trenches in the epitaxial layer, the first trenches being located in the transistor regions, and the second trenches being located in the diode regions; forming a first shielded gate oxide layer, a first shielded gate polysilicon layer, and a first isolation layer in a lower portion of each first trench, and forming a second shielded gate oxide layer, a second shielded gate polysilicon layer, and a second isolation layer in a lower portion of each second trench; forming a control gate oxide layer and a control gate polysilicon layer in an upper portion of each first trench, and forming a third shielded gate oxide layer and a third shielded gate polysilicon layer in an upper portion of each second trench; and forming body regions, source regions, and a source metal layer, the body regions being located in an upper surface layer of the epitaxial layer, the source regions being located in an upper surface layer of the P-type body region, and the source metal layer being electrically connected to the body regions and the source regions, wherein the control gate polysilicon layer is located above the first shielded gate polysilicon layer and is separated from the first shielded gate polysilicon layer by the first isolation layer, the first shielded gate oxide layer is located between the first shielded gate polysilicon layer and the first trenches, and sidewalls and a bottom of the control gate polysilicon layer are wrapped by the control gate oxide layer; and the third shielded gate polysilicon layer is located above the second shielded gate polysilicon layer and is separated from the second shielded gate polysilicon layer by the second isolation layer, the second shielded gate oxide layer is located between the second shielded gate polysilicon layer and the second trenches, and sidewalls and a bottom of the third shielded gate polysilicon layer are wrapped by the third shielded gate oxide layer.

Another example of the present disclosure relates to a shielded gate trench device. The shielded gate trench device includes: a base layer including a substrate and an epitaxial layer located on the substrate, the base layer is divided into transistor regions and diode regions alternately arranged along a predetermined direction; first trenches and second trenches formed in the epitaxial layer, the first trenches being located in the transistor regions, and the second trenches being located in the diode regions; a first shielded gate oxide layer, a first shielded gate polysilicon layer, a first isolation layer, a control gate oxide layer, and a control gate polysilicon layer formed in each one of the first trenches, the control gate polysilicon layer being located above the first shielded gate polysilicon layer and being separated from the first shielded gate polysilicon layer by the first isolation layer, the first shielded gate oxide layer being located between the first shielded gate polysilicon layer and the first trench, the control gate oxide layer wrapping sidewalls and a bottom of the control gate polysilicon layer; a second shielded gate oxide layer, a second shielded gate polysilicon layer, a second isolation layer, a third shielded gate oxide layer, and a third shielded gate polysilicon layer formed in each one of the second trenches, the third shielded gate polysilicon layer being located above the second shielded gate polysilicon layer and being separated from the second shielded gate polysilicon layer by the second isolation layer, the second shielded gate oxide layer being located between the second shielded gate polysilicon layer and the second trench, the third shielded gate oxide layer wrapping sidewalls and a bottom of the third shielded gate polysilicon layer; and body regions, source regions, and a source metal layer, the body region being located in an upper surface layer of the epitaxial layer, the source region being located in an upper surface layer of the body region, and the source metal layer being electrically connected to the body regions and the source regions.

Another example of the present disclosure relates to a semiconductor device. The semiconductor device includes: a base layer having transistor regions and diode regions alternately arranged along a predetermined direction; first trenches formed in the transistor regions, wherein in each one of the first trenches, a first shielded gate polysilicon layer is formed in a lower portion of the first trench, and is isolated from the first trench by a first shielded gate oxide layer, a control gate polysilicon layer is formed in an upper portion of the first trench, sidewalls and a bottom of the control gate polysilicon layer are wrapped by a control gate oxide layer, the first shielded gate polysilicon layer is isolated from the control gate oxide layer at the bottom of the control gate polysilicon layer by the first isolation layer; and second trenches formed in the diode regions, wherein in each one of the second trenches, a second shielded gate polysilicon layer is formed in a lower portion of the second trench, and is isolated from the second trench by a second shielded gate oxide layer, a third gate polysilicon layer is formed in an upper portion of the second trench, sidewalls and a bottom of the third gate polysilicon layer are wrapped by a third gate oxide layer, the second shielded gate polysilicon layer is isolated from the third gate oxide layer at the bottom of the third gate polysilicon layer by the second isolation layer; wherein a thickness of the control gate oxide layer is greater than the third shielded gate oxide layer.

As described above, the shielded gate trench device with an MGD structure and its fabrication method according to the present disclosure integrate the MGD structure into a conventional SGT device. The base layer of the shielded gate trench device is partitioned into alternately arranged transistor regions and diode regions along a predetermined direction. First trenches are formed in the transistor regions. Second trench are formed in the diode regions. The MGD structure includes within the second trench: a second shielded-gate oxide layer; a second shielded-gate polysilicon layer; a second isolation layer; a third shielded-gate oxide layer, and a third shielded-gate polysilicon layer positioned above the second shielded-gate polysilicon layer. By incorporating the MGD structure into the semiconductor device, the present disclosure reduces source-drain voltage (Vsd) while simultaneously decreasing reverse recovery charge (Qrr) and reverse recovery time (Trr), thereby enhancing circuit efficiency. Operational mechanism during turn-off: a discharge current path is established to extract Qrr from the epitaxial layer to the upper polysilicon layer of the MGD structure (i.e., the third shielded gate polysilicon layer) for charge evacuation.

Those skilled in the art will recognize additional features and advantages upon reading the following detailed description, and upon viewing the accompanying drawings.

### BRIEF DESCRIPTION OF THE DRAWINGS

FIG. 1 shows a process flowchart of a method for fabricating a shielded gate trench device with an MGD structure according to the present disclosure.

FIG. 2 shows a schematic diagram of a base layer provided in a method for fabricating a shielded gate trench device with an MGD structure according to the present disclosure.

FIG. 3 shows a planar layout of transistor regions and diode regions.

FIG. 4 shows a schematic structural diagram presented after forming first trenches and second trenches in a method for fabricating a shielded gate trench device with an MGD structure according to the present disclosure.

FIG. 5 shows a schematic structural diagram presented after depositing a first oxide layer in a method for fabricating a shielded gate trench device with an MGD structure according to the present disclosure.

FIG. 6 shows a schematic structural diagram presented after depositing a first polysilicon layer in a method for fabricating a shielded gate trench device with an MGD structure according to the present disclosure.

FIG. 7 shows a schematic structural diagram presented after etching back a first polysilicon layer to a first predetermined depth in a method for fabricating a shielded gate trench device with an MGD structure according to the present disclosure.

FIG. 8 shows a schematic structural diagram presented after etching a first oxide layer in a method for fabricating a shielded gate trench device with an MGD structure according to the present disclosure.

FIG. 9 shows a schematic structural diagram presented after depositing a second oxide layer in a method for fabricating a shielded gate trench device with an MGD structure according to the present disclosure.

FIG. 10 shows a schematic structural diagram presented after etching back a second oxide layer C and a first oxide layer A to a second predetermined depth in a method for fabricating a shielded gate trench device with an MGD structure according to the present disclosure.

FIG. 11 shows a schematic structural diagram presented after forming a third oxide layer in a method for fabricating a shielded gate trench device with an MGD structure according to the present disclosure.

FIG. 12 shows a schematic structural diagram presented after forming a photoresist layer in a method for fabricating a shielded gate trench device with an MGD structure according to the present disclosure.

FIG. 13 shows a schematic structural diagram presented after patterning a photoresist layer in a method for fabricating a shielded gate trench device with an MGD structure according to the present disclosure.

FIG. 14 shows a schematic structural diagram presented after removing a part of a third oxide layer located on sidewalls of second trenches in a method for fabricating a shielded gate trench device with an MGD structure according to the present disclosure.

FIG. 15 shows a schematic structural diagram presented after removing a photoresist layer and forming a fourth oxide layer in a method for fabricating a shielded gate trench device with an MGD structure according to the present disclosure.

FIG. 16 shows a schematic structural diagram presented after forming a second polysilicon layer in a method for fabricating a shielded gate trench device with an MGD structure according to the present disclosure.

FIG. 17 shows a schematic structural diagram presented after patterning a second polysilicon layer in a method for fabricating a shielded gate trench device with an MGD structure according to the present disclosure.

FIG. 18 shows a schematic structural diagram presented after forming a P-type body region, an N-type source region and a source metal layer in a method for fabricating a shielded gate trench device with an MGD structure according to the present disclosure.

### DETAILED DESCRIPTION

The embodiments of the present disclosure will be specifically described below through specific examples. Those skilled in the art can easily understand the other advantages and effects of the present disclosure from the content disclosed in this description. The present disclosure may also be implemented or applied through other different specific implementations, and the details in this description may be modified or changed based on different perspectives and applications without deviating from the spirit of the present disclosure.

It should be emphasized that the term “including/comprising” when used herein refers to the presence of a feature, integral part, step, or component, but does not exclude the presence or addition of one or more other features, integral parts, steps, or components.

The features described and/or indicated for one implementation may be used in the same or similar manner in one or more other implementations, combined with features in other implementations, or substituted for features in other implementations.

When describing the embodiments of the present disclosure in detail, for ease of description, a schematic diagram representing an apparatus structure will be enlarged out of a general scale, and the schematic diagram is only an example, which should not limit the scope of protection of the present disclosure. In addition, in actual fabrication, the three-dimensional spatial dimensions of length, width, and depth should be included.

For the convenience of description, spatial relationship words such as “under”, “below”, “lower than”, “underneath”, “above” and “over” may be used here to describe the relationship between one element or feature and other elements or features shown in the figure. It is to be understood that these spatial relationship words are intended to include directions for devices in use or operation in addition those depicted in the figures. In addition, when a layer is referred to as “between” two layers, it may be the only layer between the two layers, or there may be one or more layers therebetween.

In the context of this application, a structure described where a first feature is “above” a second feature may include embodiments where the first feature and second feature form direct contact, or embodiments where additional features are formed between the first structure and second feature, such that the first feature and second feature may not be in direct contact.

It should be noted that the drawings provided in the embodiments are only intended to schematically describe the basic concept of the present disclosure. Therefore, the drawings only display the components related to the present disclosure, and are not drawn according to the number, shape, and size of the components during actual implementation. The type, number, and scale of each component during actual implementation may be freely changed, and the layout pattern of the component may also be more complex.

### Embodiment I

The present disclosure provides a method for fabricating a shielded gate trench device with an MGD (Metal-Gated Diode) structure. Referring to FIG. 1 which shows a process flowchart of this method, the method includes the following steps:

S1: providing a base layer, the base layer including an N-type substrate and an N-type epitaxial layer located on the N-type substrate, a plane where the base layer is located being divided into transistor regions and regions alternately arranged along a predetermined direction;

S2: forming first trenches and second trenches in the N-type epitaxial layer, the first trenches being located in the transistor regions, and the second trenches being located in the diode regions;

S3: forming a first shielded gate oxide layer, a first shielded gate polysilicon layer, and a first isolation layer in the first trenches, and forming a second shielded gate oxide layer, a second shielded gate polysilicon layer, and a second isolation layer in the second trenches;

S4: forming a control gate oxide layer and a control gate polysilicon layer in the first trenches, and forming a third shielded gate oxide layer and a third shielded gate polysilicon layer in the second trenches; and

S5: forming a P-type body region, an N-type source region, and a source metal layer, the P-type body region being located on an upper surface layer of the N-type epitaxial layer, the N-type source region being located on an upper surface layer of the P-type body region, and the source metal layer being electrically connected to the P-type body region and the N-type source region.

In the fabrication method according to the present disclosure, the plane where the base layer is located is divided into the transistor regions and the diode regions alternately arranged along the predetermined direction, the first trenches are formed in the transistor regions, the second trenches are formed in the diode regions, the MGD structure includes the second shielded gate oxide layer, the second shielded gate polysilicon layer, the second isolation layer, the third shielded gate oxide layer, and the third shielded gate polysilicon layer located in the second trenches, the third shielded gate polysilicon layer is located above the second shielded gate polysilicon layer and is separated from the second shielded gate polysilicon layer through the second isolation layer, and the first shielded gate polysilicon layer, the second shielded gate polysilicon layer, and the third shielded gate polysilicon layer are connected to the source potential. An existence of the MGD structure can reduce a source-drain voltage Vsd of the device, and can simultaneously reduce the reverse recovery charge Qrr and reverse recovery time Trr, thereby improving a circuit efficiency.

The steps will be described below in detail with reference to the drawings.

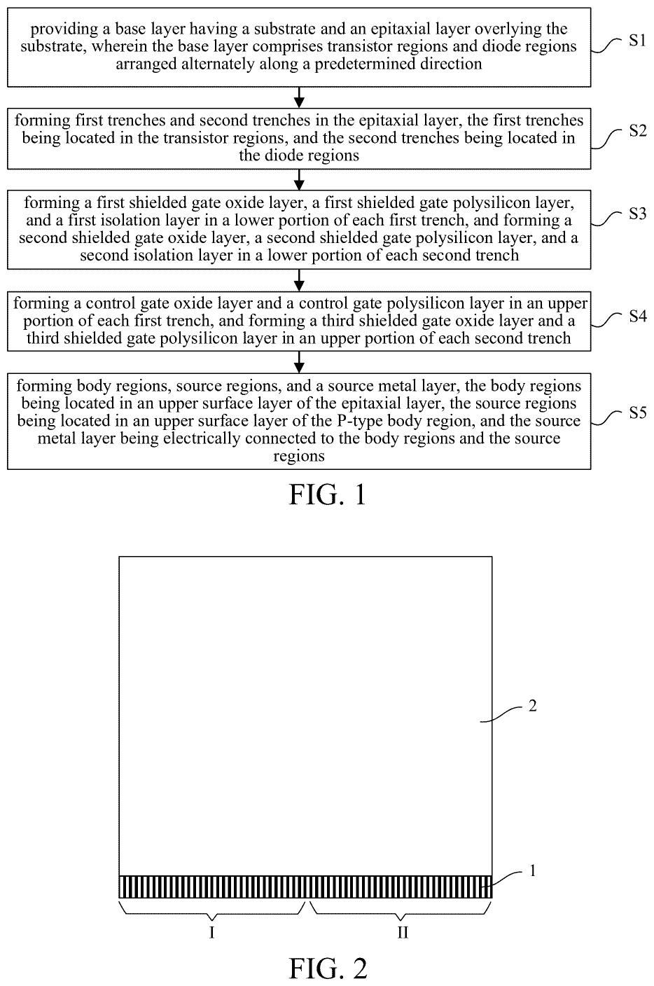

Firstly, referring to FIG. 2, step S1 is performed: A base layer is provided, the base layer includes an N-type substrate 1 and an N-type epitaxial layer 2 located on the N-type substrate 1, and a plane where the base layer is located is divided into transistor regions I and regions II alternately arranged along a predetermined direction.

As an example, a doping concentration of the N-type substrate 1 is higher than a doping concentration of the N-type epitaxial layer 2. The specific doping concentration may be adjusted according to actual needs, which is not specifically limited in the present disclosure.

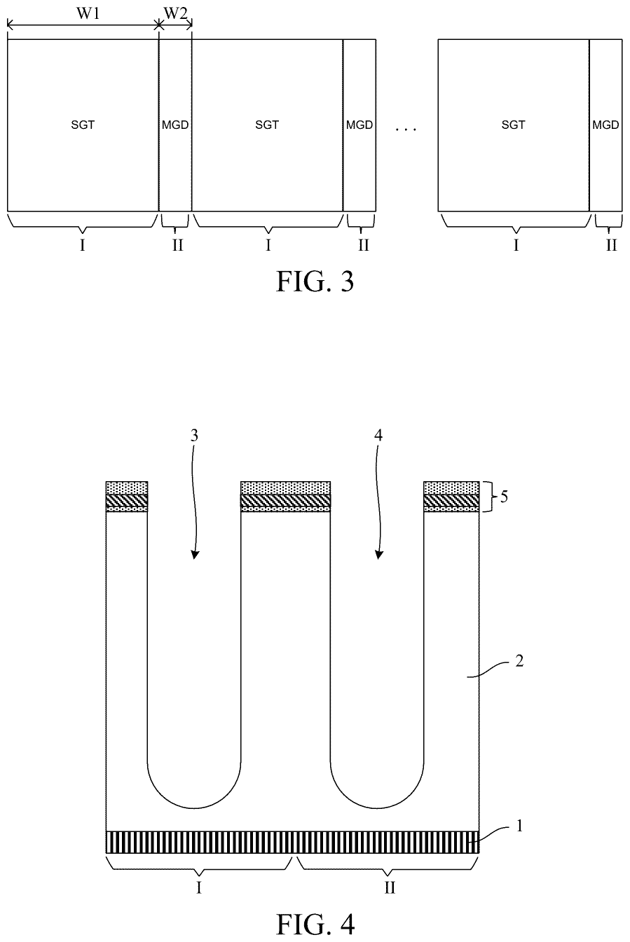

As an example, referring to FIG. 3 which shows a planar layout of the transistor regions I (SGT) and the diode regions II (MGD), a number of the transistor regions I and a number of the diode regions II are plural in number and arranged alternately in sequence. The specific number of the regions may be set according to actual needs, which is not specifically limited in the present disclosure.

As an example, FIG. 3 also shows a width W1 of the transistor region I and a width W2 of the diode region II, and the width W1 of the transistor region I is greater than the width W2 of the diode region II, which may be specifically set according to actual needs. For example, in some examples, W1 is ten times that of W2.

Then, referring to FIG. 4, step S2 is performed: First trenches 3 and second trenches 4 are formed in the N-type epitaxial layer 2 by adopting dry etching and/or wet etching, the first trenches 3 are located in the transistor regions I, and the second trenches 4 are located in the diode regions II.

As an example, a mask layer 5 is firstly formed on the N-type epitaxial layer 2, then the mask layer 5 is patterned, and the N-type epitaxial layer 2 is etched based on the patterned mask layer 5 to obtain the first trenches 3 and the second trenches 4. The mask layer 5 may adopt a multilayer structure, for example, sequentially including a silicon oxide layer, a silicon nitride layer, and a silicon oxide layer from bottom to top. The specific depth of the first trenches 3 and the second trenches 4 may be set according to actual needs, which is not specifically limited in the present disclosure.

As an example, a number of the first trenches 3 in one transistor region I is M, a number of the second trenches 4 in one adjacent diode region II is N, N≥1, and M≥N.

Specifically, a ratio of M/N may be set according to actual needs, taking into account the required source-drain voltage and effective device area. For example, in some examples, M/N≥5. In a specific example, M/N is equal to 10.

As an example, a spacing between the second trench 4 and the adjacent first trench 3 is equal to a spacing between two adjacent first trenches 3 (when M≥2), and a spacing between two adjacent second trenches 4 (when N≥2) is equal to the spacing between two adjacent first trenches 3.

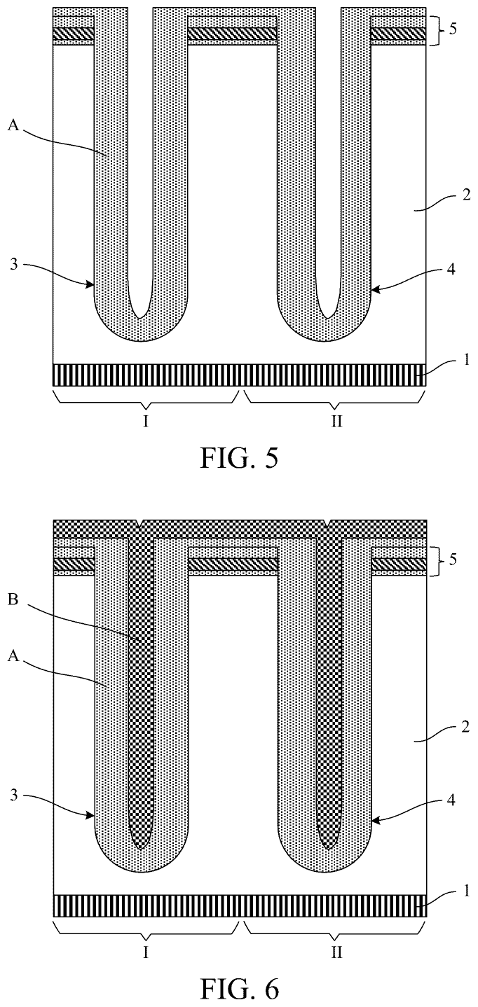

Then, referring to FIG. 5 to FIG. 9, step S3 is performed: A first shielded gate oxide layer 6, a first shielded gate polysilicon layer 7, and a first isolation layer 8 are formed in the first trenches 3, and a second shielded gate oxide layer 9, a second shielded gate polysilicon layer 10, and a second isolation layer 11 are formed in the second trenches 4.

As an example, the forming a first shielded gate oxide layer 6, a first shielded gate polysilicon layer 7, and a first isolation layer 8 in the first trenches 3, and forming a second shielded gate oxide layer 9, a second shielded gate polysilicon layer 10, and a second isolation layer 11 in the second trenches 4 include the following steps:

(1) As shown in FIG. 5, a first oxide layer A is deposited by adopting a thermal oxidation method, a chemical vapor deposition method, or other suitable methods. The first oxide layer A covers inner surfaces of the first trenches 3 and the second trenches 4. In some examples, the first oxide layer A also covers an upper surface of the mask layer 5.

(2) As shown in FIG. 6, a first polysilicon layer B is deposited. The first polysilicon layer B is filled into the first trenches 3 and the second trenches 4. In some examples, the first polysilicon layer B also covers the mask layer 5.

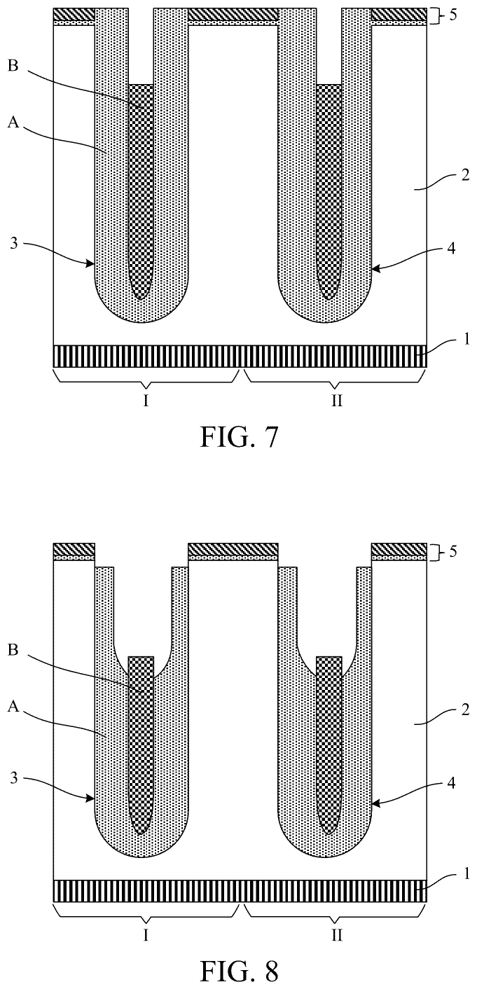

(3) As shown in FIG. 7, the first polysilicon layer B is etched back to a first predetermined depth by adopting dry etching. In some examples, the mask layer 5 is thinned in this process.

(4) As shown in FIG. 8, the first oxide layer A is etched to expose part of sidewalls of the first polysilicon layer B by adopting wet etching, so that the subsequently deposited oxide layer can better cover a top end of the first polysilicon layer B.

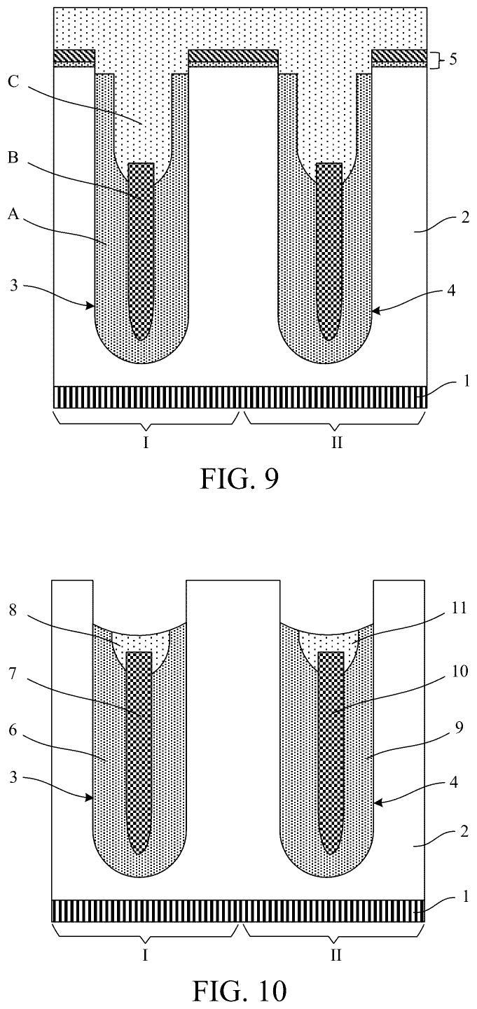

(5) As shown in FIG. 9, a second oxide layer C is deposited by adopting a chemical vapor deposition or other suitable methods. The second oxide layer C is filled into the first trenches 3 and the second trenches 4, and covers an exposed surface of the first polysilicon layer B. In some examples, the second oxide layer C also covers the mask layer 5.

(6) As shown in FIG. 10, the second oxide layer C and the first oxide layer A are etched back to a second predetermined depth. The second predetermined depth is greater than the first predetermined depth. At this time, a part of the first oxide layer A located in the first trenches 3 serves as the first shielded gate oxide layer 6, a part of the first oxide layer A located in the second trenches 4 serves as the second shielded gate oxide layer 9, a part of the first polysilicon layer B located in the first trenches 3 serves as the first shielded gate polysilicon layer 7, a part of the first polysilicon layer B located in the second trenches 4 serves as the second shielded gate polysilicon layer 10, a part of the second oxide layer C located in the first trenches 3 serves as the first isolation layer 8, and a part of the second oxide layer C located in the second trenches 4 serves as the second isolation layer 11.

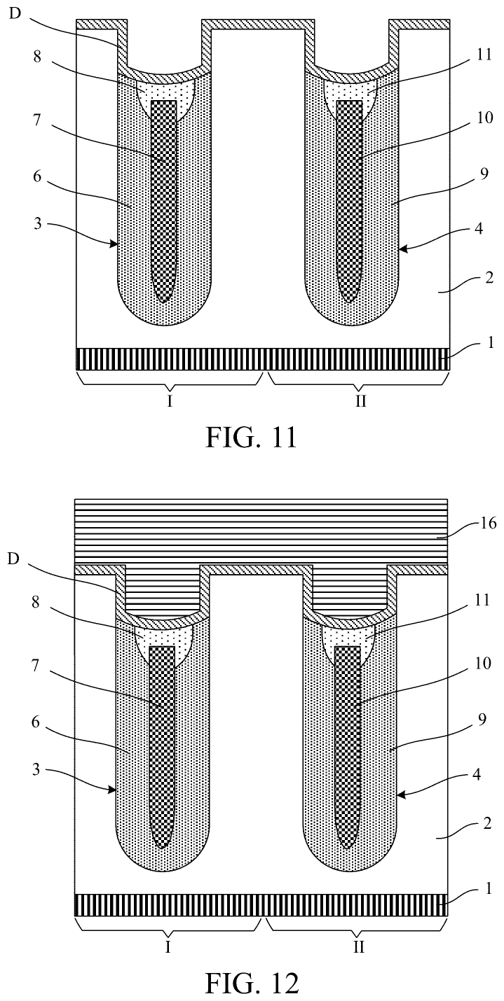

Then, referring to FIG. 11 to FIG. 17, step S4 is performed: A control gate oxide layer 12 and a control gate polysilicon layer 13 are formed in the first trenches 3, and a third shielded gate oxide layer 14 and a third shielded gate polysilicon layer 15 are formed in the second trenches 4.

As an example, the forming a control gate oxide layer 12 and a control gate polysilicon layer 13 in the first trenches 3, and forming a third shielded gate oxide layer 14 and a third shielded gate polysilicon layer 15 in the second trenches 4 include the following steps:

(1) As shown in FIG. 11, a third oxide layer D is formed by adopting a thermal oxidation method, a chemical vapor deposition method, or other suitable methods. The third oxide layer D covers exposed sidewalls of the first trenches 3 and exposed sidewalls of the second trenches 4. In some examples, the third oxide layer D also covers the N-type epitaxial layer 2, and the first isolation layer 8 and the second isolation layer 11 are also thickened.

(2) As shown in FIG. 12, a photoresist layer 16 is formed. The photoresist layer 16 covers the N-type epitaxial layer 2 and is filled into the first trenches 3 and the second trenches 4.

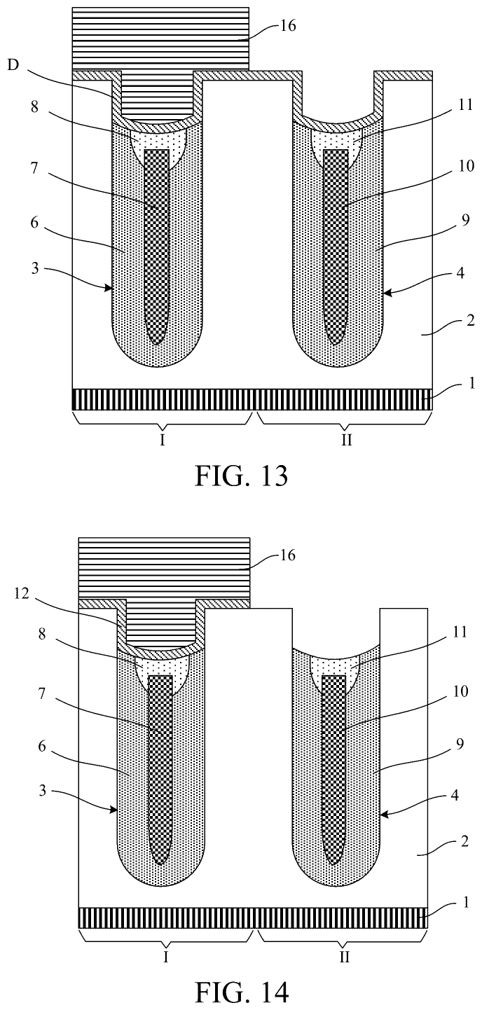

(3) As shown in FIG. 13, the photoresist layer 16 is patterned by adopting a photolithographic process to obtain an opening exposing the diode regions II.

(4) As shown in FIG. 14, a part of the third oxide layer D located on sidewalls of the second trenches 4 is removed by adopting wet etching or other suitable methods. A part of the third oxide layer D located on sidewalls of the first trenches 3 serves as the control gate oxide layer 12.

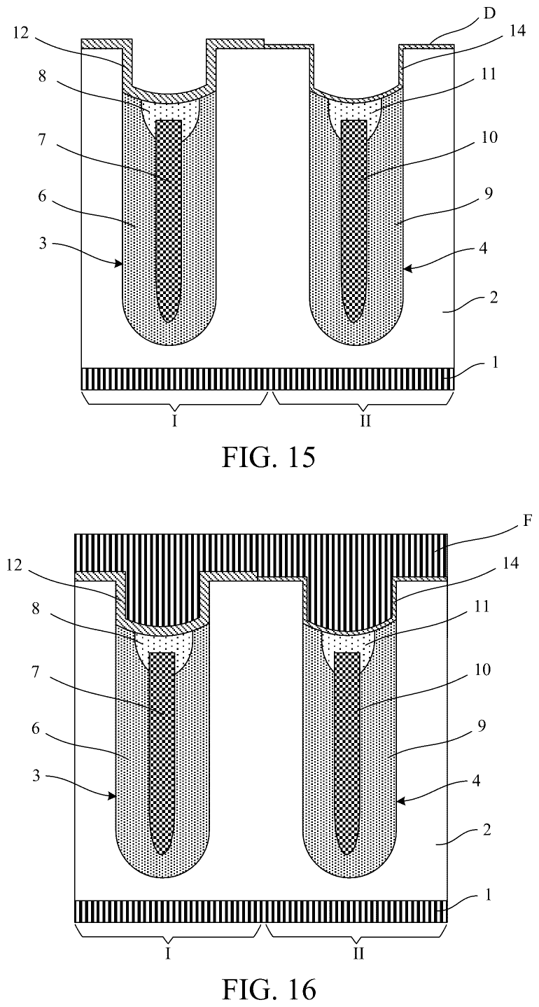

(5) As shown in FIG. 15, the photoresist layer 16 is removed and a fourth oxide layer E is formed by adopting a thermal oxidation method, a chemical vapor deposition method, or other suitable methods. The fourth oxide layer E covers at least the exposed sidewalls of the second trenches 4. A part of the fourth oxide layer E covering the sidewalls of the second trenches 4 serves as the third shielded gate oxide layer 14. In some examples, the fourth oxide layer E also covers the N-type epitaxial layer 2, and the second isolation layer 11 is also thickened in this process.

It should be pointed out that during a formation of the fourth oxide layer E, the control gate oxide layer 12 may also be thickened to a certain extent.

(6) As shown in FIG. 16, a second polysilicon layer F is formed. The second polysilicon layer F covers the N-type epitaxial layer 2 and is filled into the first trenches 3 and the second trenches 4.

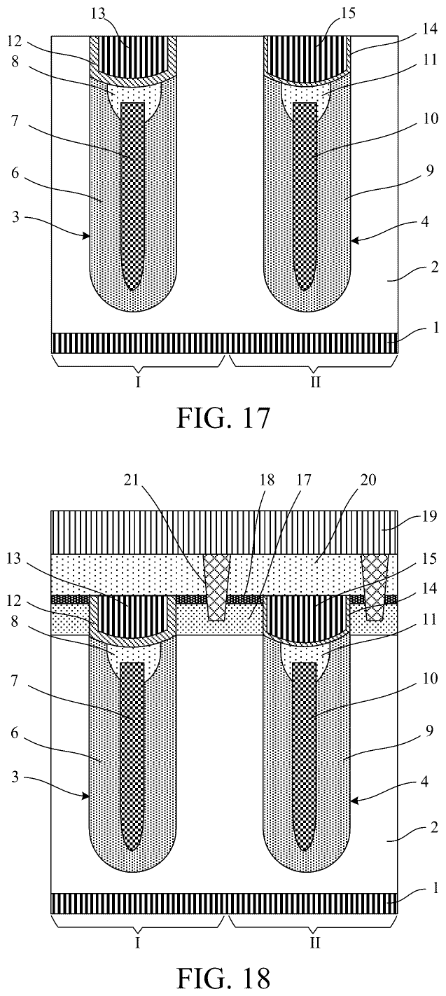

(7) As shown in FIG. 17, the second polysilicon layer F is patterned to obtain the control gate polysilicon layer 13 located in the first trenches 3 and the third shielded gate polysilicon layer 15 located in the second trenches 4.

Specifically, the control gate polysilicon layer 13 is located above the first shielded gate polysilicon layer 7 and is separated from the first shielded gate polysilicon layer 7 through the first isolation layer 8, the first shielded gate oxide layer 6 is located between an outer surface of the first shielded gate polysilicon layer 7 and inner surfaces of the first trenches 3, and the control gate oxide layer 12 is located between an outer surface of the control gate polysilicon layer 13 and the inner surfaces of the first trenches 3.

Specifically, the third shielded gate polysilicon layer 15 is located above the second shielded gate polysilicon layer 10 and is separated from the second shielded gate polysilicon layer 10 through the second isolation layer 11, the second shielded gate oxide layer 9 is located between an outer surface of the second shielded gate polysilicon layer 10 and inner surfaces of the second trenches 4, and the third shielded gate oxide layer 14 is located between an outer surface of the third shielded gate polysilicon layer 15 and the inner surfaces of the second trenches 4.

As an example, a thickness of the third shielded gate oxide layer 14 is less than a thickness of the control gate oxide layer 12. In some examples, the thickness of the third shielded gate oxide layer 14 ranges from 60 angstroms to 70 angstroms, for example, 65 angstroms. The thickness of the control gate oxide layer 12 ranges from 250 angstroms to 350 angstroms, for example, 300 angstroms.

Then, referring to FIG. 18, step S5 is performed: A P-type body region 17, an N-type source region 18, and a source metal layer 19 are formed. The P-type body region 17 is located on an upper surface layer of the N-type epitaxial layer 2. The N-type source region 18 is located on an upper surface layer of the P-type body region 17. The source metal layer 19 is electrically connected to the P-type body region 17 and the N-type source region 18.

As an example, a method for forming the P-type body region 17 and the N-type source region 18 includes ion implantation. The desired doping concentration and doping depth may be achieved by controlling the implantation dose, energy, and the like. A method for forming the source metal layer 19 includes, but not limited to, electroplating, physical vapor deposition, and the like.

Specifically, before the source metal layer 19 is formed, firstly an interlayer dielectric layer 20 is formed, and a required via 21 is formed in a predetermined position of the interlayer dielectric layer 20. The via extends downwards into the N-type source region 18 and the P-type body region 17. The via 21 is filled with a conductive material. The source metal layer 19 is electrically connected to the P-type body region 17 and the N-type source region 18 through the via 21.

Specifically, the first shielded gate polysilicon layer 7, the second shielded gate polysilicon layer 10, and the third shielded gate polysilicon layer 15 are connected to a source potential.

Specifically, the reverse recovery charge Qrr refers to an amount of charge stored in the device when the device switches from a forward on state to a reverse off state. This charge needs to be cleared when the device switches from the on state to the off state. The reverse recovery time Trr refers to a time required for the device to completely switch from the forward on state to the reverse off state. This time includes a time for the stored charge to decrease to zero and a time for the device to reach a stable state internally. Shorter Trr means that the device can switch from the on state to the off state faster. By adding a certain proportion of MGD structure in the device, the method for fabricating a shielded gate trench device according to the present disclosure helps to reduce the source-drain voltage Vsd of the device, and reduce the reverse recovery charge Qrr and the reverse recovery time Trr at the same time, thereby improving the circuit efficiency. When the device is turned off, a circuit provides draw current to draw the reverse recovery charge Qrr from the N-type epitaxial layer 2 to an upper polysilicon layer (i.e., the third shielded gate polysilicon layer 15) of the MGD structure to discharge.

### Embodiment II

This embodiment provides a shielded gate trench device with an MGD structure, and the device may be fabricated by adopting the fabrication method described in embodiment I or other suitable methods. Referring to FIG. 18 which shows a schematic structural diagram of the shielded gate trench device with an MGD structure, it includes a base layer, first trenches 3, second trenches 4, a first shielded gate oxide layer 6, a first shielded gate polysilicon layer 7, a first isolation layer 8, a control gate oxide layer 12, a control gate polysilicon layer 13, a second shielded gate oxide layer 9, a second shielded gate polysilicon layer 10, a second isolation layer 11, a third shielded gate oxide layer 14, a third shielded gate polysilicon layer 15, a P-type body region 17, an N-type source region 18, and a source metal layer 19.

Specifically, the base layer includes an N-type substrate 1 and an N-type epitaxial layer 2 located on the N-type substrate 1, a plane where the base layer is located is divided into transistor regions I and diode regions II alternately arranged along a predetermined direction, the first trenches 3 are located in the N-type epitaxial layer 2 in the transistor regions I, and the second trenches 4 are located in the N-type epitaxial layer 2 in the diode regions II.

Specifically, the first shielded gate oxide layer 6, the first shielded gate polysilicon layer 7, the first isolation layer 8, the control gate oxide layer 12, and the control gate polysilicon layer 13 are located in the first trenches 3, the control gate polysilicon layer 12 is located above the first shielded gate polysilicon layer 7 and is separated from the first shielded gate polysilicon layer 7 through the first isolation layer 8, the first shielded gate oxide layer 6 is located between an outer surface of the first shielded gate polysilicon layer 7 and inner surfaces of the first trenches 3, the control gate oxide layer 12 is located between an outer surface of the control gate polysilicon layer 13 and the inner surfaces of the first trenches 3, and the first shielded gate polysilicon layer 7 is connected to a source potential.

Specifically, the second shielded gate oxide layer 9, the second shielded gate polysilicon layer 10, the second isolation layer 11, the third shielded gate oxide layer 14, and the third shielded gate polysilicon layer 15 are located in the second trenches 4, the third shielded gate polysilicon layer 15 is located above the second shielded gate polysilicon layer 10 and is separated from the second shielded gate polysilicon layer 10 through the second isolation layer 11, the second shielded gate oxide layer 9 is located between an outer surface of the second shielded gate polysilicon layer 10 and inner surfaces of the second trenches 4, the third shielded gate oxide layer 14 is located between an outer surface of the third shielded gate polysilicon layer 15 and the inner surfaces of the second trenches 4, and the second shielded gate polysilicon layer 10 and the third shielded gate polysilicon layer 14 are connected to the source potential.

Specifically, the P-type body region 17 is located on an upper surface layer of the N-type epitaxial layer 2, the N-type source region 18 is located on an upper surface layer of the P-type body region 17, and the source metal layer 19 is electrically connected to the P-type body region 17 and the N-type source region 18.

As an example, a number of the first trenches 3 in one transistor region I is M, a number of the second trenches 4 in one adjacent diode region II is N, M and N are positive integers, N≥1, and M≥N.

Specifically, a ratio of M/N may be set according to actual needs, taking into account the required source-drain voltage and effective device area. For example, in some examples, M/N≥5. In a specific example, M/N is equal to 10.

As an example, a spacing between the second trench 4 and the adjacent first trench 3 is equal to a spacing between two adjacent first trenches 3 (when M≥2), and a spacing between two adjacent second trenches 4 (when N≥2) is equal to the spacing between two adjacent first trenches 3.

As an example, a thickness of the third shielded gate oxide layer 14 is less than a thickness of the control gate oxide layer 12. In some examples, the thickness of the third shielded gate oxide layer 14 ranges from 60 angstroms to 70 angstroms, for example, 65 angstroms. The thickness of the control gate oxide layer 12 ranges from 250 angstroms to 350 angstroms, for example, 300 angstroms.

The shielded gate trench device with an MGD structure according to the present disclosure has reduced source-drain voltage Vsd, reverse recovery charge Qrr and reverse recovery time Trr, and higher circuit efficiency.

To sum up, in the shielded gate trench device with an MGD structure and a method for fabricating the same according to the present disclosure, the MGD structure is integrated in an ordinary SGT device, the plane where the base layer is located is divided into the transistor regions and the diode regions alternately arranged along the predetermined direction, the first trenches and the second trenches are respectively formed in the transistor regions and the diode regions, the MGD structure includes the second shielded gate oxide layer, the second shielded gate polysilicon layer, the second isolation layer, the third shielded gate oxide layer, and the third shielded gate polysilicon layer located in the second trenches, the third shielded gate polysilicon layer is located above the second shielded gate polysilicon layer and is separated from the second shielded gate polysilicon layer through the second isolation layer, and the second shielded gate polysilicon layer and the third shielded gate polysilicon layer are connected to the source potential. By adding an MGD structure in the device, the present disclosure reduces the source-drain voltage Vsd of the device, and reduces the reverse recovery charge Qrr and the reverse recovery time Trr at the same time, thereby improving a circuit efficiency. When the device is turned off, a circuit provides draw current to draw the reverse recovery charge Qrr from the epitaxial layer to an upper polysilicon layer of the MGD structure to discharge. Therefore, the present disclosure effectively overcomes various disadvantages in the existing technologies and has a great industrial utilization value.

The above embodiments are only intended to exemplarily describe the principle and effect of the present disclosure, rather than to limit the present disclosure. Any person skilled in the art may modify or change the embodiments without departing from the spirit and scope of the present disclosure. Therefore, all equivalent modifications or changes completed by those with ordinary knowledge in the technical field without departing from the spirit and technical concept disclosed in the present disclosure should still be covered by the claims of the present disclosure.

What is claimed is:

1. A method for fabricating a shielded gate trench device, comprising:
providing a base layer having a substrate and an epitaxial layer overlying the substrate, wherein the base layer comprises transistor regions and diode regions arranged alternately along a predetermined direction;
forming first trenches and second trenches in the epitaxial layer, the first trenches being located in the transistor regions, and the second trenches being located in the diode regions;
forming a first shielded gate oxide layer, a first shielded gate polysilicon layer, and a first isolation layer in a lower portion of each first trench, and forming a second shielded gate oxide layer, a second shielded gate polysilicon layer, and a second isolation layer in a lower portion of each second trench;
forming a control gate oxide layer and a control gate polysilicon layer in an upper portion of each first trench, and forming a third shielded gate oxide layer and a third shielded gate polysilicon layer in an upper portion of each second trench; and
forming body regions, source regions, and a source metal layer, the body regions being located in an upper surface layer of the epitaxial layer, the source regions being located in an upper surface layer of the P-type body region, and the source metal layer being electrically connected to the body regions and the source regions, wherein
the control gate polysilicon layer is located above the first shielded gate polysilicon layer and is separated from the first shielded gate polysilicon layer by the first isolation layer, the first shielded gate oxide layer is located between the first shielded gate polysilicon layer and the first trenches, and sidewalls and a bottom of the control gate polysilicon layer are wrapped by the control gate oxide layer; and
the third shielded gate polysilicon layer is located above the second shielded gate polysilicon layer and is separated from the second shielded gate polysilicon layer by the second isolation layer, the second shielded gate oxide layer is located between the second shielded gate polysilicon layer and the second trenches, and sidewalls and a bottom of the third shielded gate polysilicon layer are wrapped by the third shielded gate oxide layer.

2. The method for fabricating a shielded gate trench device of claim 1, wherein forming a first shielded gate oxide layer, a first shielded gate polysilicon layer, and a first isolation layer in a lower portion of each first trench, and forming a second shielded gate oxide layer, a second shielded gate polysilicon layer, and a second isolation layer in a lower portion of each second trench comprises:
depositing a first oxide layer, the first oxide layer covering inner surfaces of the first trenches and the second trenches;
depositing a first polysilicon layer, the first polysilicon layer being filled into the first trenches and the second trenches;
etching back the first polysilicon layer to a first predetermined depth;
corroding the first oxide layer to expose partial sidewalls of the first polysilicon layer;
depositing a second oxide layer, the second oxide layer being filled into the first trenches and the second trenches and covering an exposed surface of the first polysilicon layer; and
etching back the second oxide layer and the first oxide layer back to a second predetermined depth, the second predetermined depth being less than the first predetermined depth, the part of the first oxide layer located in the first trenches serving as the first shielded gate oxide layer, the part of the first oxide layer located in the second trenches serving as the second shielded gate oxide layer, the part of the first polysilicon layer located in the first trenches serving as the first shielded gate polysilicon layer, the part of the first polysilicon layer located in the second trenches serving as the second shielded gate polysilicon layer, the part of the second oxide layer located in the first trenches serving as the first isolation layer, the part of the second oxide layer located in the second trenches serving as the second isolation layer.

3. The method for fabricating a shielded gate trench device of claim 1, wherein forming a control gate oxide layer and a control gate polysilicon layer in an upper portion of each first trench, and forming a third shielded gate oxide layer and a third shielded gate polysilicon layer in an upper portion of each second trench comprises:
conformally forming a third oxide layer over inner surfaces of the first trenches, the second trenches, and a top surface of the epitaxial layer, wherein the third oxide layer covers exposed inner surfaces of the first trenches after forming the first isolation layer and the first shielded gate oxide layer, and exposed inner surfaces of the second trenches after forming the second isolation layer and the second shielded gate oxide layer;
depositing a photoresist layer, the photoresist layer covering the epitaxial layer and being filled into the first trenches and the second trenches;
patterning the photoresist layer to obtain openings exposing the diode regions;
removing the third oxide layer in the openings exposing the diode regions, wherein the remained third oxide layer serves as the control gate oxide layer;
removing the photoresist layer and forming a fourth oxide layer covering the top surface of the epitaxial layer, wherein the fourth oxide layer covers at least exposed inner surfaces of the second trenches;
forming a second polysilicon layer, the second polysilicon layer covering the top surface of the epitaxial layer and being filled into the first trenches and the second trenches; and
patterning the second polysilicon layer to obtain the control gate polysilicon layer located in the first trenches and the third shielded gate polysilicon layer located in the second trenches.

4. The method for fabricating a shielded gate trench device of claim 1, wherein a number of the first trenches in one of the transistor regions is M, a number of the second trenches in the diode region adjacent to the one of the transistor regions is N, and wherein M and N are positive integers, N≥1, and M≥N.

5. The method for fabricating a shielded gate trench device of claim 4, wherein M/N≥5.

6. The method for fabricating a shielded gate trench device of claim 1, wherein a thickness of the third shielded gate oxide layer is less than a thickness of the control gate oxide layer.

7. The method for fabricating a shielded gate trench device of claim 6, wherein the thickness of the third shielded gate oxide layer ranges from 60 angstroms to 70 angstroms, and the thickness of the control gate oxide layer ranges from 250 angstroms to 350 angstroms.

8. A shielded gate trench device, comprising:
a base layer comprising a substrate and an epitaxial layer located on the substrate, the base layer is divided into transistor regions and diode regions alternately arranged along a predetermined direction;
first trenches and second trenches formed in the epitaxial layer, the first trenches being located in the transistor regions, and the second trenches being located in the diode regions;
a first shielded gate oxide layer, a first shielded gate polysilicon layer, a first isolation layer, a control gate oxide layer, and a control gate polysilicon layer formed in each one of the first trenches, the control gate polysilicon layer being located above the first shielded gate polysilicon layer and being separated from the first shielded gate polysilicon layer by the first isolation layer, the first shielded gate oxide layer being located between the first shielded gate polysilicon layer and the first trench, the control gate oxide layer wrapping sidewalls and a bottom of the control gate polysilicon layer;
a second shielded gate oxide layer, a second shielded gate polysilicon layer, a second isolation layer, a third shielded gate oxide layer, and a third shielded gate polysilicon layer formed in each one of the second trenches, the third shielded gate polysilicon layer being located above the second shielded gate polysilicon layer and being separated from the second shielded gate polysilicon layer by the second isolation layer, the second shielded gate oxide layer being located between the second shielded gate polysilicon layer and the second trench, the third shielded gate oxide layer wrapping sidewalls and a bottom of the third shielded gate polysilicon layer; and
body regions, source regions, and a source metal layer, the body region being located in an upper surface layer of the epitaxial layer, the source region being located in an upper surface layer of the body region, and the source metal layer being electrically connected to the body regions and the source regions.

9. The shielded gate trench device of claim 8, wherein a number of the first trenches in one of the transistor regions is M, a number of the second trenches in an adjacent diode region is N, and wherein M and N are positive integers, N≥1, and M≥N.

10. The shielded gate trench device of claim 9, wherein M/N≥5.

11. The shielded gate trench device of claim 8, wherein a thickness of the third shielded gate oxide layer is less than a thickness of the control gate oxide layer.

12. The shielded gate trench device of claim 8, wherein a thickness of the third shielded gate oxide layer ranges from 60 angstroms to 70 angstroms, and a thickness of the control gate oxide layer ranges from 250 angstroms to 350 angstroms.

13. A semiconductor device, comprising:
a base layer comprising transistor regions and diode regions alternately arranged along a predetermined direction;
first trenches formed in the transistor regions, wherein in each one of the first trenches, a first shielded gate polysilicon layer is formed in a lower portion of the first trench, and is isolated from the first trench by a first shielded gate oxide layer, a control gate polysilicon layer is formed in an upper portion of the first trench, sidewalls and a bottom of the control gate polysilicon layer are wrapped by a control gate oxide layer, the first shielded gate polysilicon layer is isolated from the control gate oxide layer at the bottom of the control gate polysilicon layer by the first isolation layer; and
second trenches formed in the diode regions, wherein in each one of the second trenches, a second shielded gate polysilicon layer is formed in a lower portion of the second trench, and is isolated from the second trench by a second shielded gate oxide layer, a third gate polysilicon layer is formed in an upper portion of the second trench, sidewalls and a bottom of the third gate polysilicon layer are wrapped by a third gate oxide layer, the second shielded gate polysilicon layer is isolated from the third gate oxide layer at the bottom of the third gate polysilicon layer by the second isolation layer;
wherein a thickness of the control gate oxide layer is greater than the third shielded gate oxide layer.

14. The semiconductor device of claim 13, wherein a number of the first trenches in one of the transistor regions is M, and a number of the second trenches in an diode region adjacent to the one of the transistor regions is N, and wherein M and N are positive integers, N≥1, and M≥N.

15. The semiconductor device of claim 14, wherein M/N≥5.

16. The semiconductor device of claim 13, wherein the thickness of the third shielded gate oxide layer ranges from 60 angstroms to 70 angstroms.

17. The semiconductor device of claim 13, wherein the thickness of the control gate oxide layer ranges from 250 angstroms to 350 angstroms.

18. The semiconductor device of claim 13, wherein the base layer comprises:
a substrate;
an epitaxial layer overlying the substrate, wherein the first trenches and the second trenches are extended from a top surface into an interior of the epitaxial layer;
body regions formed in an upper surface layer of the epitaxial layer;
source regions formed in the body regions; and
a source metal layer electrically connected to the body regions and the source regions.
